(19) United States
(12) Patent Application Publication
(10) Pub. No.: US 2024/0288487 A1
(43) Pub. Date: Aug. 29, 2024

(54) SEMICONDUCTOR STRUCTURE

(71) Applicant: MediaTek Singapore Pte. Ltd., Singapore (SG)

(72) Inventors: Jubao ZHANG, Singapore (SG); Zhigang DUAN, Singapore (SG); Chang LIANG, Singapore (SG); Lian DUAN, Singapore (SG)

(21) Appl. No.: 18/414,741

(22) Filed: Jan. 17, 2024

Related U.S. Application Data
(60) Provisional application No. 63/486,670, filed on Feb. 24, 2023.

(51) Int. Cl. G01R 31/26

(52) U.S. Cl. CPC G01R 31/2644; G01R 31/2621

(57) ABSTRACT

A semiconductor structure is provided. The semiconductor structure includes a semiconductor wafer and a test structure. The semiconductor wafer has a substrate having a scribe line area and die areas. The die areas are separated by the scribe line area. The test structure is disposed in the scribe line area. The test structure includes an isolation feature, a first transistor test device, a second transistor test device. The isolation feature is located in the substrate. The first transistor test device and the second transistor test device are disposed on opposite sides of the isolation feature. Channels of the first transistor test device and the second transistor test device have the same conductivity type. A first gate electrode of the first transistor test device and a second gate electrode of the second transistor test device have opposite conductivity types.

### CROSS REFERENCE TO RELATED APPLICATIONS

This application claims the benefit of U.S. Provisional Application No. 63/486,670, filed Feb. 24, 2023, the entirety of which is incorporated by reference herein.

### BACKGROUND OF THE INVENTION

### Field of the Invention

The present invention relates to a semiconductor structure, and, in particular, to a test structure disposed in a scribe line area of a semiconductor wafer.

### Description of the Related Art

During the integrated circuit manufacturing process, integrated circuit (IC) dies are formed on a single semiconductor wafer. The integrated circuit dies are arranged in an array with scribe line areas between them. In addition, the scribe line areas are provided for placement of test keys to test different properties of the semiconductor wafer so as to maintain and assure device quality. After the integrated circuit dies are manufactured on the semiconductor wafer, the integrated circuit dies are separated along the scribe line areas using a singulation process for the subsequent packaging processes.

Thus, an appropriate test key structure for monitoring the finished product is needed.

### BRIEF SUMMARY OF THE INVENTION

An embodiment of the present invention provides a semiconductor structure. The semiconductor structure includes a semiconductor wafer and a test structure. The semiconductor wafer has a substrate having a scribe line area and die areas. The die areas are separated by the scribe line area. The test structure is disposed in the scribe line area. The test structure includes an isolation feature, a first transistor test device, a second transistor test device. The isolation feature is located in the substrate. The first transistor test device and the second transistor test device are disposed on opposite sides of the isolation feature. Channels of the first transistor test device and the second transistor test device have the same conductivity type. A first gate electrode of the first transistor test device and a second gate electrode of the second transistor test device have opposite conductivity types.

In some embodiments, the first gate electrode further comprises first gate doped regions located on opposite edges of the first gate electrode that are adjacent to the first source doped region and the first drain doped region, wherein the first gate doped regions and the second gate electrode have the same conductivity type. In some embodiments, the first gate doped regions are formed in upper portions of the first gate electrode. In some embodiments, the first transistor test device is disposed in a first active region surrounded by the isolation feature. The first transistor test device includes a first well region, a first gate structure, a first source doped region and a first drain doped region. The first well region is located in the substrate. The first well region and the first gate electrode have the same conductivity type. The first gate structure including the first gate electrode is disposed on the substrate. The first source doped region and the first drain doped region are disposed on the first well region and adjacent to the first gate structure. The first source doped region, the first drain doped region and the first well region have opposite conductivity types. In some embodiments, the second transistor test device disposed in a second active region surrounded by the isolation feature. The second transistor test device includes the first well region, a second gate structure, a second source doped region and a second drain doped region. The second gate structure including the second gate electrode is disposed on the substrate. The second source doped region and the second drain doped region are disposed on the first well region and adjacent to the second gate structure. The second source doped region, the second drain doped region and the first well region have opposite conductivity types. In some embodiments, a distance between the first active region and the second active region is equal to the minimum distance of non-abutting active regions of the design rule.

In some embodiments, the test structure further includes a first bulk doped region and a second bulk doped region. The first bulk doped region is located on the first well region in a third active region surrounded by the isolation feature. The second bulk doped region is located on the first well region in a fourth active region surrounded by the isolation feature. The first active region, the second active region, the third active region and the fourth active region are separated from each other. In some embodiments, the first transistor test device has a first channel length and a first channel width that is the same as the first channel length, and wherein the second transistor test device has a second channel length and a second channel width. The second channel length and the second channel width are same as the first channel length. In some embodiments, the test structure further includes a first test pad, a second test pad, a third test pad, a fourth test pad, a fifth test pad and a sixth test pad. The first test pad is electrically connected to the first gate structure. The second test pad is electrically connected to the first source doped region. The third test pad is electrically connected to the first drain doped region. The fourth test pad is electrically connected to the second gate structure. The fifth test pad is electrically connected to the second source doped region. The sixth test pad is electrically connected to the second drain doped region. In some embodiments, the test structure further includes a seventh test pad and an eighth test pad. The seventh test pad is electrically connected to the first bulk doped region. The eighth test pad is electrically connected to the second bulk doped region.

An embodiment of the present invention provides a semiconductor structure. The semiconductor structure includes a semiconductor wafer and a test structure. The semiconductor wafer has a substrate having a scribe line area and die areas. The die areas are separated by the scribe line area. The test structure is disposed in the scribe line area. The test structure includes a first active region, a second active region, a first gate electrode, a first source doped region, a first drain doped region, a second gate electrode, a second source doped region and a second drain doped region. The first active region and the second active region are located in a first well region of a first conductivity type in the substrate and separated from each other. The first gate electrode of the first conductivity type is disposed in the first active region. The first source doped region and the first drain doped region of a second conductivity type are disposed on the first well region and adjacent to the first gate structure. The second gate electrode of the second conductivity type is disposed in the second active region. The second source doped region and the second drain doped region of the second conductivity type are disposed on the first well region and adjacent to the second gate structure.

In some embodiments, the first gate electrode further comprises first gate doped regions of the second conductivity type located on opposite edges of the first gate electrode that are adjacent to the first source doped region and the first drain doped region. In some embodiments, the first gate doped regions are formed in upper portions of the first gate electrode. In some embodiments, the semiconductor structure further includes a first isolation feature disposed in the substrate. The first active region and the second active region are adjacent to opposite sides of the isolation feature. In some embodiments, the test structure further includes a third active region, a fourth active region, a first bulk doped region and a second bulk doped region. The third active region and the fourth active region are located in the first well region in the substrate and separated from each other. The first bulk doped region is located on the first well region in the third active region. The second bulk doped region is located on the first well region in the fourth active region. In some embodiments, the second active region and the third active region are disposed on opposite sides of the first active region. In some embodiments, the first active region and the fourth active region are disposed on opposite sides of the second active region. In some embodiments, the first well region, the first bulk doped region and the second bulk doped region have the first conductivity type. In some embodiments, the first well region, a first gate structure including the first gate electrode, the first source doped region and the first drain doped region form a first transistor test device. The first well region, a second gate structure including the second gate electrode, the second source doped region and the second drain doped region form a second transistor test device. In some embodiments, the first transistor test device is a flipped gate NMOS transistor, and the second transistor test device is an NMOS transistor. In some embodiments, the first transistor test device and the second transistor test device are the same size. In some embodiments, the first gate structure, the first source doped region, the first drain doped region, the first bulk doped region, the second gate structure, the second source doped region, the second drain doped region and the second bulk doped region are electrically connected to different test pads in the scribe line area.

### BRIEF DESCRIPTION OF THE DRAWINGS

The present invention can be more fully understood by reading the subsequent detailed description and examples with references made to the accompanying drawings, wherein:

FIG. 1 is a schematic top view of a semiconductor wafer in accordance with some embodiments of the disclosure;

FIG. 2 is an enlarged top view of the FIG. 1, showing the arrangement of scribe line areas and die areas;

FIG. 3 is an enlarged top view of the FIG. 2, showing the arrangement of test structures in accordance with some embodiments of the disclosure;

FIG. 4A is a cross-sectional view of the test structure along the A-A′ line of FIG. 3 in accordance with some embodiments of the disclosure;

FIG. 4B is a cross-sectional view of the test structure along the A-A′ line of FIG. 3 in accordance with some embodiments of the disclosure;

FIG. 4C is a cross-sectional view of the test structure along the B-B′ line of FIG. 3 in accordance with some embodiments of the disclosure; and

FIG. 4D is a cross-sectional view of the test structure along the C-C′ line of FIG. 3 in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

Analog circuits incorporate voltage and current reference circuits extensively. Such reference circuits are DC quantities that exhibit little dependence on supply and process parameters and a well-defined dependence on the temperature. For example, bandgap reference circuits are probably the most popular high performance reference circuits, with the principle thereof to implement components having characteristics of positive temperature coefficient and negative temperature coefficient and add/minus the voltages or current of these components in a predetermined proportion to generate a value independent of temperature, such value output as a reference. The conventional bandgap reference circuits have a stable low reference voltage at around 1.25V which is almost equal to the silicon energy gap at 0K. A kind of current bandgap reference circuits is composed of a flipped gate N-type metal-oxide-semiconductor field effect transistor (flipped gate NMOS FET (also called FGD)) and a plurality of N-type metal-oxide-semiconductor field effect transistors (NMOS FETs (also called NGDs)) surrounding the flipped gate NMOS FET. And the threshold voltage difference of the flipped gate NMOS FET and the NMOS FET may be output as the reference voltage (it is also called VBGR (VBGR=Vt(FGD)−Vt(NGD))) of bandgap reference circuit. However, there is no testkey similar to the flipped gate NMOS FET in the die areas for wafer acceptance test (WAT) of electrical performances. Therefore, a novel test key structure to monitor the flipped gate NMOS FET in the die areas is needed.

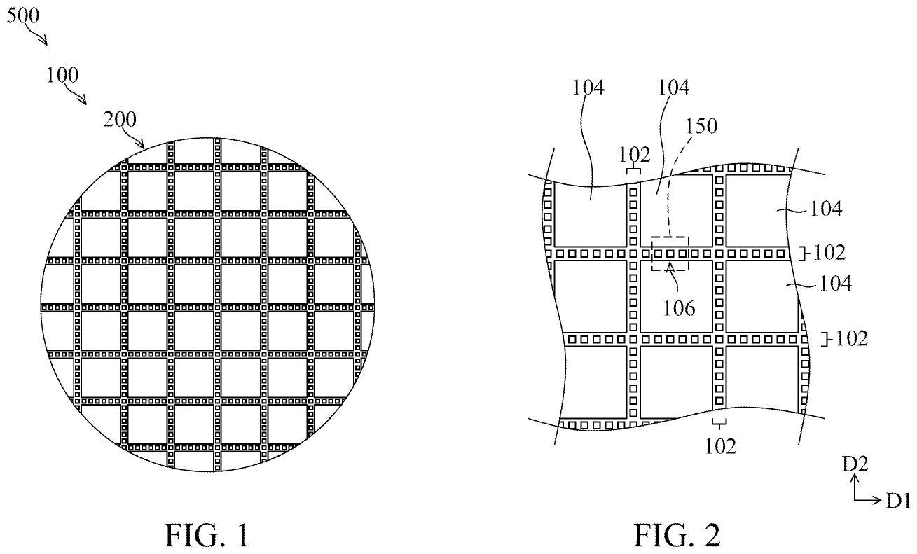

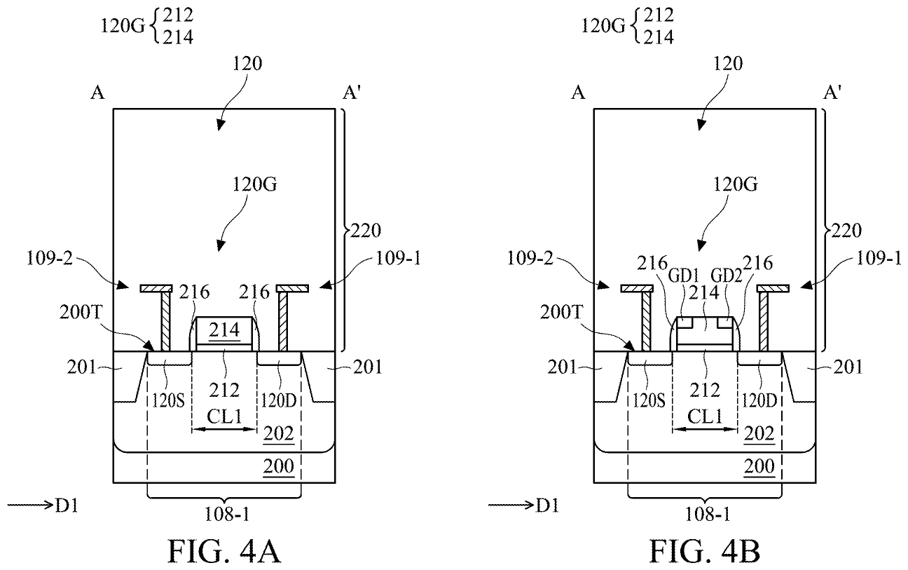

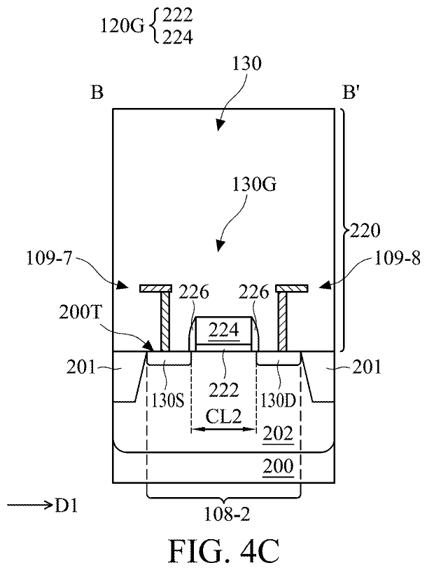

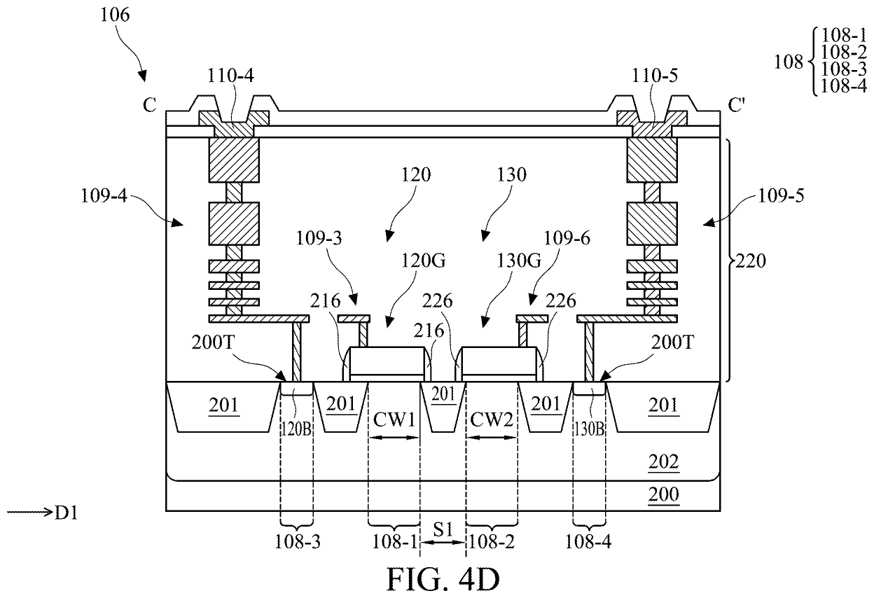

FIG. 1 is a schematic top view of a semiconductor wafer 100 of a semiconductor structure 500 in accordance with some embodiments of the disclosure. FIG. 2 is an enlarged top view of the FIG. 1, showing the arrangement of scribe line areas 102 and die areas 104. As shown in FIGS. 1-2, the semiconductor wafer 100 has a substrate 200 (would be described in FIGS. 4A, 4B, 4C and 4D) having scribe line areas 102 and die areas 104. The adjacent die areas 104 are separated by the scribe line areas 102. In some embodiment, the scribe line areas 102 are defined on the substrate 200 and extend along different directions D1 and D2. In addition, the direction D1 may be substantially perpendicular to the direction D2. In some embodiments, the substrate 200 may comprise silicon. In alternative embodiments, SiGe, bulk semiconductor, strained semiconductor, compound semiconductor, semiconductor-on-insulator (SOI), and other commonly used semiconductor substrates can be used for the substrate 200. In some embodiment, the substrate 200 may have a first conductivity type such as P-type, or a second conductivity type such as N-type, depending on requirements.

In some embodiment, the scribe line areas 102 are used to separate die areas 104 and provided spaces for the singulation process (including sawing, laser grooving or other applicable singulation processes) to cut the semiconductor wafer 100 into individual semiconductor dies (i.e., the separated die areas 104) without damaging the semiconductor dies. In some embodiment, the scribe line areas 102 are also provided spaces for one or more test structures 106 disposed therein without occupying the space for the die areas 104. In addition, the test structures 106 may be removed after the semiconductor wafer 100 is subjected the singulation process.

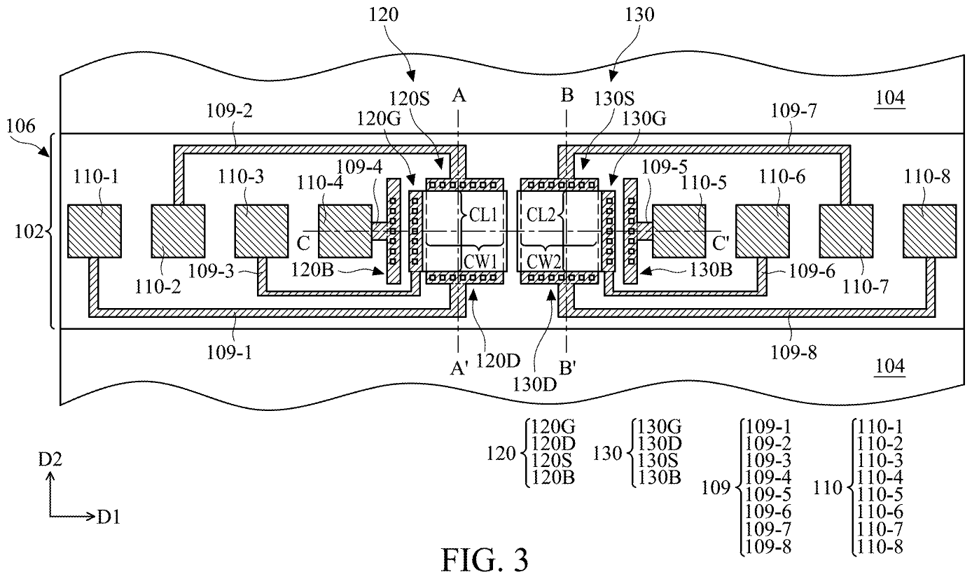

FIG. 3 is an enlarged top view of a region 150 of the FIG. 2, showing the arrangement of test structures 106 in accordance with some embodiments of the disclosure. FIGS. 4A and 4B are a cross-sectional views of a transistor test device 120 of the test structure 106 along the A-A′ line of FIG. 3 in accordance with some embodiments of the disclosure. FIG. 4C is a cross-sectional view transistor test devices 130 of the test structure 106 along the B-B′ line of FIG. 3 in accordance with some embodiments of the disclosure. FIG. 4D is a cross-sectional view of the test structure 106 along the C-C′ line of FIG. 3 in accordance with some embodiments of the disclosure. For illustration of the relationship of the electrical connections between the terminals of the test structure 106 and corresponding test pads 110, portions of interconnection structure 220 (e.g., interlayer dielectrics (ILD)) between the test structure 106 and the test pads 110 may be hidden to expose portions of the test structure 106 and contacts/vias/conductive traces (drawn in solid lines) of interconnection structure 220 in the side views of FIGS. 4A, 4B, 4C and 4D.

In some embodiment, the test structure 106 includes active regions 108 (including active regions 108-1, 108-2, 108-3 and 108-4), the transistor test devices 120 and 130 and test pads 110 (including test pads 110-1, 110-2, 110-3, 110-4, 110-5, 110-6, 110-7 and 110-8). In some embodiment, the transistor test devices 120 and 130 have physical characteristics similar to transistor devices (not shown) fabricated in one of the die areas 104. In addition, the transistor test devices 120 and 130 and the transistor devices (not shown) in one of the die areas 104 may be formed using the same fabrication processes. In some embodiment, channels of the transistor test devices 120 and 130 have the same conductivity type. For example, the transistor test device 120 may be a flipped gate N-type metal-oxide-semiconductor field effect transistor (flipped gate NMOS FET (also called FGD)) having a physical structure similar to a flipped gate NMOS FET in one of the die areas 104. In addition, the transistor test device 120 in the scribe line area 102 and the flipped gate NMOS FET in one of the die areas 104 may be formed sing the same fabrication processes. For example, the transistor test device 130 may be an N-type metal-oxide-semiconductor field effect transistor (NMOS FET (also called NGD)) having a physical structure similar to an NMOS FET in one of the die areas 104. In addition, the transistor test device 130 in the scribe line area 102 and the NMOS FET in one of the die areas 104 may be formed sing the same fabrication processes. The transistor test devices 120 and 130 are disposed in the scribe line areas 102 for testing to ensure that processing of subsequent device elements of the does not cause the resulting current bandgap reference circuits to fail.

One or more isolation features 201, such as shallow trench isolation (STI) features or local oxidation of silicon (LOCOS) features, may be disposed in the substrate 200. In addition, the isolation features 201 may surround the active regions 108-1, 108-2, 108-3 and 108-4. In some embodiment, the isolation features 201 are configured to provide physical and electrical isolation between the transistor test devices 120 and 130 and other test devices (not shown) in the scribe line area 102 or semiconductor devices (not shown) in the die areas 104.

As shown in FIGS. 4A, 4B, 4C and 4D, a well region 202 is formed in a portion of the substrate 200 underlying the isolation features 201. The well region 202 may extend from a top surface 200T of the substrate 200 into a portion of the substrate 200. In some embodiment, the well region 202 may have the first conductivity type, for example P-type. In other words, the well region 202 may be a p-type well (PW) region 202. The active regions 108-1, 108-2, 108-3 and 108-4 may be located in the well region 202.

The transistor test devices 120 and 130 are formed in the adjacent active regions 108-1, 108-2 and separated from each other by the isolation feature 201. In addition, the transistor test devices 120 and 130 are disposed on opposite sides of the isolation feature 201 along the direction D1. That is to say, the transistor test devices 120 and 130 are separated from each other by other test devices (not shown).

In some embodiment, the transistor test device 120, for example, a flipped gate NMOS FET, includes the well region 202, a gate structure 120G, a source doped region 120S and a drain doped region 120D.

The gate structure 120G is disposed on the substrate 200 in the active region 108-1. The gate structure 120G is formed over the well region 202. In addition, the gate structure 120G extends to cover a portion of isolation features 201 adjacent to active region 108-1 along the direction D1, as shown in FIG. 4D. In some embodiment, the gate structure 120G includes a gate dielectric layer 212 and a gate electrode 214.

The gate dielectric layer 212 is formed on the top surface 200T of the substrate 200. The gate dielectric layer 212 may comprise silicon oxide, silicon nitride, silicon oxynitride (SiON) or any other applicable dielectric materials.

The gate electrode 214 is formed over the gate dielectric layer 212. In some embodiments as shown in FIG. 4A, the gate electrode 214 may have the first conductivity type, for example P-type. In other words, the well region 202 and the gate electrode 214 may have the same conductivity type. In some embodiments as shown in FIG. 4B, the gate electrode 214 may further includes gate doped regions GD1 and GD2. The gate doped regions GD1 and GD2 may be located on opposite edges of the gate electrode 214. In addition, the gate doped regions GD1 and GD2 may be formed in upper portions of the gate electrode 214. In some embodiments, the gate doped regions GD1 and GD2 may have the second conductivity type, for example N-type. In other words, the gate electrode 214 and the gate doped regions GD1 and GD2 may have opposite conductivity types. The gate electrode 214 may comprise polycrystalline-silicon (poly-Si), poly-crystalline silicon-germanium (poly-SiGe) or any other applicable conductive materials. In some embodiments, the gate structure 120G is formed by a deposition process and a subsequent patterning process.

The gate spacers 216 are formed on sidewalls of the gate dielectric layer 212 and the gate electrode 214. In some embodiments, the gate spacers 216 includes a dielectric material such as silicon oxide (SiO₂), silicon nitride (SiN), silicon carbide (SiC), silicon oxynitride (SiON), silicon carbon nitride (SiCN), silicon oxide carbonitride (SiOCN), or any other applicable dielectric materials. In some embodiments, the gate spacers 216 are conformally formed by a deposition process and a subsequent etching back process. The deposition process may be performed to form the dielectric material over a top surface and the sidewalls of the gate structure 120G. The deposition process may comprise chemical vapor deposition (CVD), flowable chemical vapor deposition, subatmospheric chemical vapor deposition (SACVD), physical vapor deposition (PVD), atomic layer deposition (ALD), or any other applicable deposition processes. The etching back process may be performed to remove a portion the dielectric material over the top surface of the gate structure 120G, thereby exposing the gate electrode 214 and form the gate spacers 216. The etching back process may comprise wet etching, dry etching or a combination thereof.

The source doped region 120S and the drain doped region 120D are disposed in the substrate 200. The source doped region 120S and the drain doped region 120D are formed on the well region 202 and adjacent to the gate structure 120G. In addition, the gate doped regions GD1 and GD2 are respectively adjacent to the source doped region 120S and the drain doped region 120D in the top view shown in FIG. 3. In some embodiments, the source doped region 120S and the drain doped region 120D may have the second conductivity type, for example N-type.

In some embodiment, the transistor test device 130, for example, an NMOS FET, includes the well region 202, a gate structure 130G, a source doped region 130S and a drain doped region 130D.

The gate structure 130G is disposed on the substrate 200 in the active region 108-2. The gate structure 130G is formed over the well region 202. In addition, the gate structure 130G extends to cover a portion of isolation features 201 adjacent to active region 108-2 along the direction D1, as shown in FIG. 4C. In some embodiment, the gate structure 130G includes a gate dielectric layer 222 and a gate electrode 224. In some embodiment, the gate dielectric layers 212 and 222 may have the same or similar materials and fabrication processes. The gate electrodes 214 and 224 may have the same or similar materials and fabrication processes.

In some embodiments, the gate electrode 224 may have the second conductivity type, for example N-type. In other words, the gate electrode 214 of the transistor test device 120 (e.g., the flipped gate NMOS FET) and the gate electrode 224 of the transistor test device 130 (e.g., the NMOS FET) may have opposite conductivity types.

The gate spacers 226 are formed on sidewalls of the gate dielectric layer 222 and the gate electrode 224. In some embodiments, the gate spacers 216 and 226 may have the same or similar materials and fabrication processes.

The test structure 106 further includes a bulk doped region 120B for the transistor test device 120 and a bulk doped region 130B for the transistor test device 130. The bulk doped region 120B is located on the well region 202 in the active region 108-3. The active region 108-3 is disposed close to the active region 108-1. In addition, the active regions 108-2 and 108-3 are disposed on opposite sides of the active region 108-1. The bulk doped region 130B is located on the well region 202 in the active region 108-4. The active region 108-4 is disposed close to the active region 108-2. In addition, the active regions 108-1 and 108-4 are disposed on opposite sides of the active region 108-2. In some embodiments, the bulk doped regions 120B, 130B and the well region 202 may have the same conductivity type (the first conductivity type), for example P-type.

In some embodiments, the separated transistor test devices 120 and 130 of the test structure 160 are the same size, in order to better monitor the threshold voltage difference of the flipped gate NMOS FET and the NMOS FET (e.g., the reference voltage VBGR (VBGR=Vt(FGD)−Vt(NGD))). For example, the transistor test devices 120 and 130 of the test structure 160 may have the same channel length and the same channel width. In some embodiments, a channel length CL1 of the transistor test device 120 may be the same as a channel length CL2 of the transistor test device 130. For example, a channel width CW1 of the transistor test device 120 may be the same as a channel width CW2 of the transistor test device 130.

In some embodiments, the separated transistor test devices 120 and 130 of the test structure 160 may be disposed as close as possible in order to reduce the geometric variances. In addition, the arrangement of the transistor test devices 120 and 130 may be similar to that of the flipped gate NMOS FET and the NMOS FETs of the bandgap reference circuits in the die areas 104. For example, a distance S1 between the active region 108-1 (for the transistor test device 120 formed within) and the second active region 108-2 (for the transistor test device 130 formed within) in the direction D1 is equal to the minimum distance of non-abutting active regions of the design rule.

In some embodiment, the semiconductor structure 500 further includes an interconnection structure 220 formed on the substrate 200 and the test structure 106. In addition, the interconnection structure 220 is configured electrically connected to various terminals of the corresponding test structure 106. In some embodiment, the interconnection structure 220 includes various contacts/vias/conductive traces disposed in multilayer interlayer dielectrics (ILD) (not shown). In some embodiment, the contacts/vias/conductive traces include a conductive material, such as copper (Cu), aluminum (Al), tungsten (W), titanium (Ti), titanium nitride (TiN), tantalum (Ta), tantalum nitride (TaN), or another applicable material. In some embodiment, the interlayer dielectrics may include silicon oxide, silicon oxynitride, un-doped silicate glass (USG), borosilicate glass (BSG), phosphoric silicate glass (PSG), borophosphosilicate glass (BPSG), fluorinated silicate glass (FSG), carbon doped oxide, porous carbon doped silicon dioxide, a polymer such as polyimide or silicon oxycarbide polymer (SiOC), or combinations thereof. The contacts and the vias may be alternately arranged with and electrically connected to the conductive traces belong to various conductive layers of the interconnection structure 220. However, it should be noted that the number of contacts/vias/conductive traces and the number of interlayer dielectrics shown in FIGS. 4A-4D is only an example and is not a limitation to the present invention.

As shown in FIGS. 3 and 4A-4D, conductive traces 109 (including conductive traces 109-1, 109-2, 109-3, 109-4, 109-5, 109-6, 109-7 and 109-8) of the interconnection structure 220 may be electrically connected to the corresponding test pads 110 (including the test pads 110-1 to 110-8). In addition, the transistor test devices 120 and 130 are disposed between the corresponding test pads 110 in the direction D1 in the top view as shown in FIG. 3. The transistor test devices 120 and 130 are disposed below and electrically connected to the test pads 110 (FIG. 4C). In some embodiment, the test pads 110 are portions of a topmost conductive layer of the interconnection structure 220. The test pads 110 are exposed to openings of a passivation layer (not shown). In some embodiment, the test pads 110 are aluminum (Al), copper (Cu). However, it should be noted that the number of test pads 110 shown in FIGS. 1, 2, and 3 is only an example and is not a limitation to the present invention.

In some embodiment, the gate structure 120G, the source doped region 120S, the drain doped region 120D and the bulk doped region 120B of the transistor test device 120, and the gate structure 130G, the source doped region 130S, the drain doped region 130D and the bulk doped region 130B of the transistor test device 130 are electrically connected to different test pads 110 in the scribe line area 102. For example, the drain doped region 120D, the source doped region 120S, the gate structure 120G and the bulk doped region 120B (the pickup doped region of the well region 202) of the transistor test device 120 may be electrically connected to the corresponding test pads 110-1, 110-2, 110-3 and 110-4 by the conductive traces 109-1, 109-2, 109-3 and 109-4, respectively. For example, the bulk doped region 130B, the gate structure 130G, the source doped region 130S and the drain doped region 130D (the pickup doped region of the well region 202) of the transistor test device 130 may be electrically connected to the corresponding test pads 110-5, 110-6, 110-7 and 110-8 by the conductive traces 109-5, 109-6, 109-7 and 109-8, respectively. Therefore, the transistor test devices 120 and 130 may be individually measured for the testing of various physical characteristic variables, such as strain, doping type or concentration, the critical dimension of the devices (such as channel length, channel width, gate oxide thickness), electrical performances (such as threshold voltage, saturation current or leakage current), or other useful characteristics. It is noted that the relationships of the electrical connections (including the conductive traces 109) between the terminals of the transistor test device 120, 130 and the corresponding test pads 110 are not limited to the disclosed embodiment.

Embodiments provide a semiconductor structure including a test structure disposed in a scribe line area of a semiconductor wafer. In some embodiments, the test structure is a combo structure of a flipped gate NMOS FET test device and an NMOS FET test device arranged as close as possible and separated from each other. The channels of the flipped gate NMOS FET test device and the NMOS FET test device may have the same conductivity type. The gate electrode of the flipped gate NMOS FET test device and a second gate electrode of the NMOS FET test device have opposite conductivity types. In some embodiments, the flipped gate NMOS FET test device may further includes separated gate doped regions located on opposite edges of the gate electrode of the flipped gate NMOS FET test device that are adjacent to the first source doped region and the first drain doped region. The gate doped regions and the gate electrode of the flipped gate NMOS FET test device have opposite conductivity types. In addition, the flipped gate NMOS FET test device and the NMOS FET test device may have the same channel length and channel width. In some embodiments, the distance between the active regions for the flipped gate NMOS FET test device and the NMOS FET test device may be equal to the minimum distance of non-abutting active regions of the design rule. In some embodiments, the gate structures, the source doped regions, the drain doped regions and the bulk doped regions (the terminals) of the flipped gate NMOS FET test device and the NMOS FET test device are electrically connected to different test pads in the scribe line area. Therefore, the flipped gate NMOS FET test device and the NMOS FET test device can be individually measured to obtain the VBGR test result (Vt(FGD)−Vt(NDG) (i.e., the threshold voltage of the flipped gate NMOS FET test device minus the threshold voltage of the NMOS FET test device)). The reference voltage (VBGR) of bandgap reference circuit related to the fabrication process and/or tool variations (e.g., doping type or concentration, the critical dimension of the devices (such as channel length, channel width, gate oxide thickness), electrical performances (such as threshold voltage, saturation current or leakage current), or other useful characteristics) can be easily detected from the combo test structure. Compared with the VBGR result obtained by testing the finished product fabricated in a long manufacturing cycle time (about two months), the combo test structure may effectively provide the VBGR test result in a reduced cycle time (about 1.5 weeks). The fabrication yield of the finished product can be improved.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a semiconductor wafer having a substrate having a scribe line area and die areas, wherein the die areas are separated by the scribe line area; and
a test structure disposed in the scribe line area, comprising:
an isolation feature located in the substrate; and
a first transistor test device and a second transistor test device disposed on opposite sides of the isolation feature, wherein channels of the first transistor test device and the second transistor test device have the same conductivity type, and wherein a first gate electrode of the first transistor test device and a second gate electrode of the second transistor test device have opposite conductivity types.

2. The semiconductor structure as claimed in claim 1, wherein the first gate electrode further comprises first gate doped regions located on opposite edges of the first gate electrode that are adjacent to the first source doped region and the first drain doped region, wherein the first gate doped regions and the second gate electrode have the same conductivity type.

3. The semiconductor structure as claimed in claim 2, wherein the first gate doped regions are formed in upper portions of the first gate electrode.

4. The semiconductor structure as claimed in claim 1, wherein the first transistor test device is disposed in a first active region surrounded by the isolation feature and comprises:
a first well region located in the substrate, wherein the first well region and the first gate electrode have the same conductivity type;
a first gate structure comprising the first gate electrode disposed on the substrate; and
a first source doped region and a first drain doped region disposed on the first well region and adjacent to the first gate structure, wherein the first source doped region, the first drain doped region and the first well region have opposite conductivity types.

5. The semiconductor structure as claimed in claim 4, wherein the second transistor test device is disposed in a second active region surrounded by the isolation feature and comprises:
the first well region located in the substrate;
a second gate structure comprising the second gate electrode disposed on the substrate; and
a second source doped region and a second drain doped region disposed on the first well region and adjacent to the second gate structure, wherein the second source doped region, the second drain doped region and the first well region have opposite conductivity types.

6. The semiconductor structure as claimed in claim 5, wherein a distance between the first active region and the second active region is equal to a minimum distance of non-abutting active regions of the design rule.

7. The semiconductor structure as claimed in claim 5, wherein the test structure further comprises:
a first bulk doped region located on the first well region in a third active region surrounded by the isolation feature; and
a second bulk doped region located on the first well region in a fourth active region surrounded by the isolation feature, wherein the first active region, the second active region, the third active region and the fourth active region are separated from each other.

8. The semiconductor structure as claimed in claim 1, wherein the first transistor test device has a first channel length and a first channel width that is the same as the first channel length, and wherein the second transistor test device has a second channel length and a second channel width, wherein the second channel length and the second channel width are same as the first channel length.

9. The semiconductor structure as claimed in claim 6, wherein the test structure further comprises:
a first test pad electrically connected to the first gate structure;
a second test pad electrically connected to the first source doped region;
a third test pad electrically connected to the first drain doped region;
a fourth test pad electrically connected to the second gate structure;
a fifth test pad electrically connected to the second source doped region; and
a sixth test pad electrically connected to the second drain doped region.

10. The semiconductor structure as claimed in claim 7, the test structure further comprises:
a seventh test pad electrically connected to the first bulk doped region; and
an eighth test pad electrically connected to the second bulk doped region.

11. A semiconductor structure, comprising:
a semiconductor wafer having a substrate having a scribe line area and die areas, wherein the die areas are separated by the scribe line area; and
a test structure disposed in the scribe line area, comprising:
a first active region and a second active region located in a first well region of a first conductivity type in the substrate and separated from each other;
a first gate electrode of the first conductivity type disposed in the first active region;
a first source doped region and a first drain doped region of a second conductivity type disposed on the first well region and adjacent to the first gate structure;
a second gate electrode of the second conductivity type disposed in the second active region; and
a second source doped region and a second drain doped region of the second conductivity type disposed on the first well region and adjacent to the second gate structure.

12. The semiconductor structure as claimed in claim 11, wherein the first gate electrode further comprises first gate doped regions of the second conductivity type located on opposite edges of the first gate electrode that are adjacent to the first source doped region and the first drain doped region.

13. The semiconductor structure as claimed in claim 12, wherein the first gate doped regions are formed in upper portions of the first gate electrode.

14. The semiconductor structure as claimed in claim 11, further comprising a first isolation feature disposed in the substrate, wherein the first active region and the second active region are adjacent to opposite sides of the isolation feature.

15. The semiconductor structure as claimed in claim 11, wherein the test structure further comprises:
a third active region and a fourth active region located in the first well region in the substrate and separated from each other;
a first bulk doped region located on the first well region in the third active region; and
a second bulk doped region located on the first well region in the fourth active region.

16. The semiconductor structure as claimed in claim 15, wherein the second active region and the third active region are disposed on opposite sides of the first active region.

17. The semiconductor structure as claimed in claim 15, wherein the first active region and the fourth active region are disposed on opposite sides of the second active region.

18. The semiconductor structure as claimed in claim 17, wherein the first well region, the first bulk doped region and the second bulk doped region have the first conductivity type.

19. The semiconductor structure as claimed in claim 15, wherein the first well region, a first gate structure comprising the first gate electrode, the first source doped region and the first drain doped region form a first transistor test device, and wherein the first well region, a second gate structure comprising the second gate electrode, the second source doped region and the second drain doped region form a second transistor test device.

20. The semiconductor structure as claimed in claim 19, wherein the first transistor test device is a flipped gate NMOS transistor, and the second transistor test device is an NMOS transistor.

21. The semiconductor structure as claimed in claim 20, wherein the first transistor test device and the second transistor test device are the same size.

22. The semiconductor structure as claimed in claim 19, wherein the first gate structure, the first source doped region, the first drain doped region, the first bulk doped region, the second gate structure, the second source doped region, the second drain doped region and the second bulk doped region are electrically connected to different test pads in the scribe line area.
